(19) United States
(12) Patent Application Publication
(10) Pub. No.: US 2005/0140455 A1
(43) Pub. Date: Jun. 30, 2005

(54) POWER AMPLIFYING MODULE

(76) Inventor: Chun-Hsueh Chu, Taipei City (TW)

Correspondence Address: NORTH AMERICA INTERNATIONAL PATENT OFFICE (NAIPC), P.O. BOX 506, MERRIFIELD, VA, 22116, US

(21) Appl. No.: 10/710,058

(22) Filed: Jun. 16, 2004

(30) Foreign Application Priority Data
Dec. 25, 2003 (TW) 092136837

(51) Int. Cl. H03F 3/68

(52) U.S. Cl. 330/310

(57) ABSTRACT

A power amplifying module includes an input end for inputting power, an output end for outputting amplified power, and an amplifier cascade. Each amplifier comprises at least a heterojunction bipolar transistor (HBT) connected with each other in a parallel manner. The closer the amplifier to the input end is, the smaller the number of HBTs the amplifier has.

### BACKGROUND OF INVENTION

1. Field of the Invention

The present invention relates to a power amplifying module, and more specifically, to an optimal heterojunction bipolar transistor (HBT) power amplifier.

2. Description of the Prior Art

With the rapid development of the communication industry, power amplifier integrated circuits using HBTs are suitable for a wide range of applications and are particularly well adapted for use as high power microwave amplifiers such as those used in mobile phones.

In fact, in order to improve the amplifying effect, it is important to design multi-stage amplifiers. Two factors, maximum power gain and linearity, are used to determine the effect of an amplifier. Please refer to FIG. 1, which shows a relationship of a ratio of input power to average input power versus a ratio of output power to average output power, in which curve A indicates an ideal power of the amplifier, curve B indicates an actual power of the amplifier, and input 1 dB compression point IP_{1dB} and output 1 dB compression point OP_{1dB} indicate the point on curve B in which a difference of 1 dB between curve A and curve B is obtained. From FIG. 1, the larger the input 1 dB compression point IP_{1dB} is, the better the linearity is.

Generally speaking, an amplifier consists of at least a HBT coupled in parallel. A frequent and often serious problem with HBT power amplifiers is excessive heat buildup. Power amplifier integrated circuits operate at high current density, and hence high power density, and thus, heat generated by devices of the HBT elevates junction temperature significantly above ambient temperature. High junction temperature degrades the device reliability and limits the maximum power density of the device. Additionally, operating at higher power density risks thermal runaway of the power amplifier, in which the power amplifier suffers catastrophic device failure. Furthermore, operating at a higherjunction temperature reduces device mean time to failure (MTTF). Typically, it is an important issue to design an amplifier using fewer HBTs and keeping the linearity effect.

### SUMMARY OF INVENTION

It is therefore a primary objective of the claimed invention to provide a power amplifying module, to solve the above-mentioned problem.

According to the claimed invention, a power amplifying module includes an input end for inputting power, an output end for outputting amplified power, and two cascaded power amplifiers, each comprising at least a heterojunction bipolar transistor (HBT) coupled in parallel, wherein the number of HBTs of the amplifier closer to the input end is less than that of the amplifier closer to the output end.

According to the claimed invention, a method of forming a power amplifying module includes a step of cascading two power amplifiers of which the power amplifier closer to the input end has a smaller number of heterojunction bipolar transistors (HBTs) coupled in parallel than the power amplifier closer to the output end does.

These and other objects of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 shows a relationship of a ratio of input power to average input power versus a ratio of output power to average output power

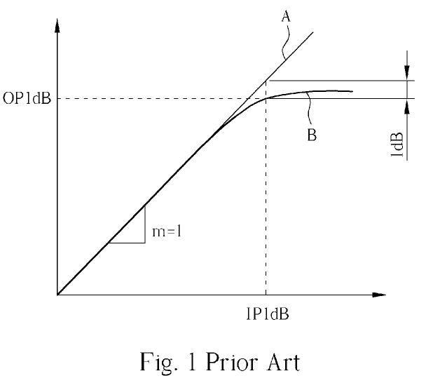

FIG. 2 is a schematic diagram of power amplifying module according to the present invention.

FIG. 3 is a circuit diagram of a power amplifier comprising a number of HBTs in parallel.

FIG. 4 shows a relationship chart of power gain, an input 1 dB compression point IP_{1dB}, and an output 1 dB compression point OP_{1dB} versus a various number of parallel HBTs.

FIG. 5 is a relationship diagram in accordance with FIG. 4

### DETAILED DESCRIPTION

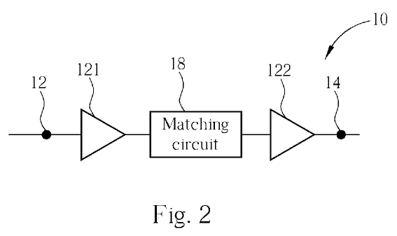

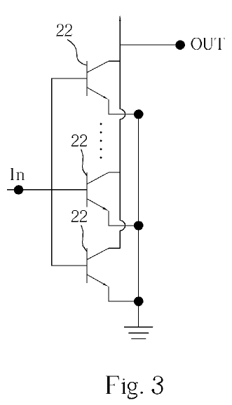

Please refer to FIGS. 2 and 3. FIG. 2 is a schematic diagram of a power amplifying module 10 according to the present invention. FIG. 3 is a circuit diagram of a power amplifier comprises a number of HBTs 22 in parallel. A power amplifying module 10 comprises an input end 12 for inputting power, an output end 14 for outputting amplified power, and two cascade power amplifiers 121, 122, where the power amplifier 121 is connected with the input end 12 and the power amplifier 122 is connected with the output end 14. As shown in FIG. 3, each of power amplifiers 121, 122 comprises at least one HBT in parallel, where IN indicates an input of a power amplifier and OUT indicates an output of a power amplifier. A matching circuit 18 is connected between the two power amplifiers 121, 122, and is used for matching power thereof.

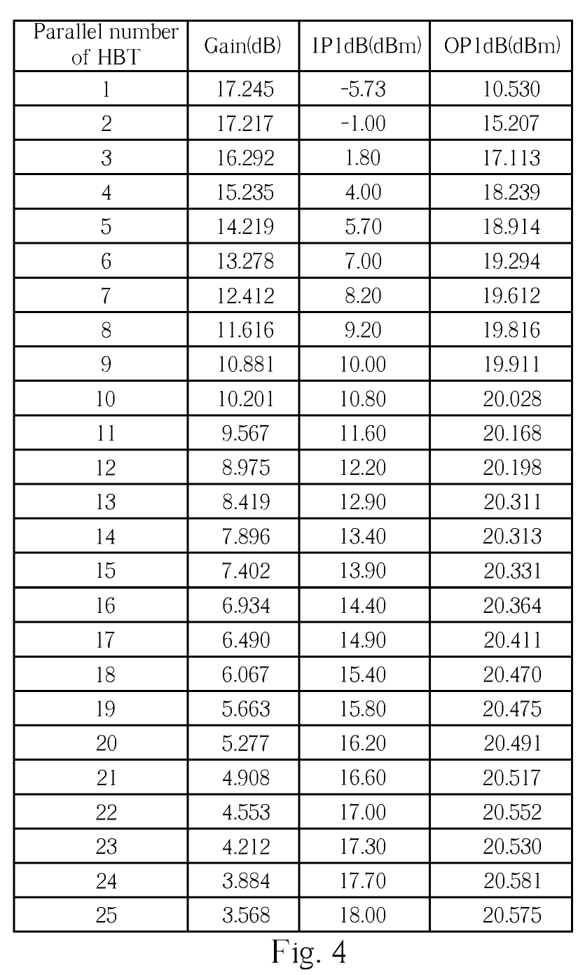

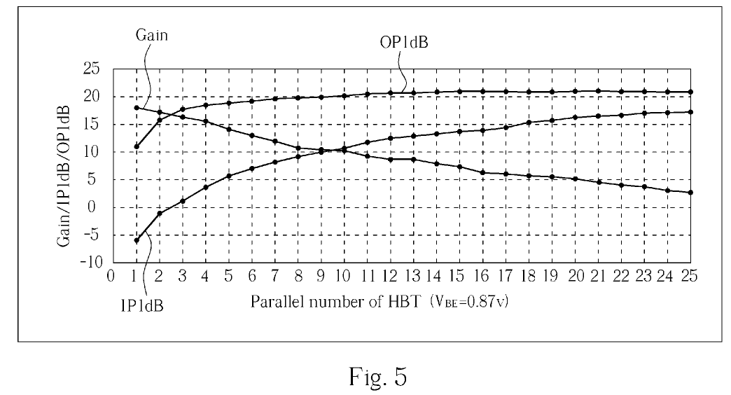

Please refer to FIGS. 2, 3 in conjunction with FIGS. 4, 5. FIG. 4 shows a relationship chart of power gain, an input 1 dB compression point IP_{1dB}, and an output 1 dB compression point OP_{1dB} versus a various number of parallel HBTs 22. FIG. 5 is a relationship diagram in accordance with FIG. 4, where a bias voltage of each HBT is 0.87V and both resistances of an input resistor and output resistor are 50 ohms. From FIGS. 4, and 5, the higher the number of the parallel HBTs is, the less the power gain of the power amplifier is and the larger both the input 1 dB compression point IP_{1dB} and an output 1 dB compression point OP_{1dB} are. In other words, the higher the parallel number of the HBTs 22 is, the worse the amplifying effect is, but the better a linearity (i.e. an improvement of distortion) is. Please notice that if more than 8 HBTs are parallel connected, an output 1 dB compression point OP_{1dB} tends towards a constant value.

Additionally, the data shown in FIGS. 4 and 5 is measured under both the input impendence and the output impendence of 50 ohms. The higher the number of HBTs formed in an amplifier is, the smaller the measured power gain of the amplifier is, as well as the larger both the input 1 dB compression point IP_{1dB} and output 1 dB compression point OP_{1dB} are. But the value of the output 1 dB compression point OP_{1dB} will tend towards a constant when the number of the HBTs 22 of an amplifier is over a threshold. For convenience, the associated data as follows is based on FIGS. 4 and 5.

Please refer to FIGS. 2, 4 and 5. Suppose that the input power of −5 dBm is to be amplified to 20 dBm, an amplifier module 10 having 25 dBm power gain is required, of which the amplifier 121 closer to the input end 12 has 4 parallelly-coupled HBTs 22, and the amplifier 122 closer to the output end 11 has 11 parallelly-coupled HBTs 22, respectively. The reason the differentnumbers of the HBTs of the amplifiers 121, 122 are chosen results from the fact that the input power of −5 dBm is smaller than the 1 dB compression point IP_{1dB-121} of the amplifier 121 (i.e. 5.7 dBm), and the 10.235 dBm output power of the amplifier 121 available is smaller than both the output 1 dB compression point OP_{1dB-121} of the amplifier 121 (i.e. 18.239 dBm) and the input 1 dB compression point IP_{1dB-122} of the amplifier 122 (i.e. 11.6 dBm). In doing so, the output power via the amplifier 121 is not distorted at all and does not exceed a limitation of the input power of the next amplifier 122. Finally, the output power via the amplifier 122 is 19.802 dBm, which is lower than the output 1 dB compression pointOP_{1dB-122} of the amplifier 122 (i.e. 20.168 dBm), meaning that the output power is still not distorted. Generally speaking, a matching circuit 18 is arranged between the two amplifiers 121, 122 for matching the output power of the amplifier 121 with the input power of the amplifier 122 for preventing power loss.

The input power of −5 dBm is smaller than the 1 dB compression point IP_{1dB-121} of the amplifier 121 (i.e. 5.7 dBm), and the 10.235 dBm available output power of the amplifier 121 is smaller than both the output 1 dB compression point OP_{1dB-121} of the amplifier 121 (i.e. 18.239 dBm) and the input 1 dB compression point IP_{1dB-122} of the amplifier 122 (i.e. 11.6 dBm). In doing so, the output power via the amplifier 121 is not distorted at all and does not exceed a limitation of the input power of the next amplifier 122. Finally, the output power via the amplifier 122 is 19.802 dBm, which is lower than the output 1 dB compression pointOP_{1dB-122} of the amplifier 122 (i.e. 20.168 dBm), meaning that the output power is still not distorted.

Suppose that the input power of −5 dBm remains, but amplifiers 121, 122 are swapped. Input power of −5 dBm is smaller than the input 1 dB compression point IP_{1dB-121} of the amplifier 122 (i.e. 11.6 dBm) and 4.567 dBm output power of the amplifier 122 available is smaller than both the output 1 dB compression point OP_{1dB-122} of the amplifier 122 (i.e. 20.168 dBm) and the input 1 dB compression point IP_{1dB-121} of the amplifier 121 (i.e. 5.7 dBm). In doing so, the output power via the amplifier 122 is not distorted at all and does not exceed a limitation of the input power of the next amplifier 121. Afterwards, the output power via the amplifier 121 is 19.802 dBm, which is larger than the output 1 dB compression point OP_{1dB-121} of the amplifier 121 (i.e. 18.239 dBm), meaning that the output power is distorted. Consequently, if the power amplifier comprising a higher number of HBTs is set close to the input end, distortion is more likely.

Certainly, the number of the HBTs contained in the amplifiers 121, 122 is not limited to the above combination. For example, the amplifier 121 can be formed by 5 HBTs coupled in parallel, and the amplifier 122 can be formed by 10 HBTs 22 coupled in parallel. But the amplifier 121 close to the input end should have a smaller number of coupled-in-parallel HBTs than the amplifier 122 close to the output end does.

From FIG. 4, the power amplifier having only one HBT 22 has a power gain of 17.245 and a minimum output 1 dB compression point of OP_{1dB}. If the designer requires the output power of up to 10.6 dBm and the gain of over 17.245, the concept of the present invention facilitates design efficiency.

Notice that although the data of the output 1 dB compression point OP_{1dB} shown in FIGS. 4 and 5 is obtained under the condition of both the input impendence and output impendence being 50 ohms, a similar tend, in which the output 1 dB compression point OP_{1dB} tends towards to a constant (about 20.5 dBm) as output 1 dB compression pointOP_{1dB} increases, remains. If necessary, a designer can adjust both input impendence and output impendence to change the constant of the output 1 dB compression pointOP_{1dB.} To sum up, the concept of controlling the amplifier close to the input end to have a lower number of HBTs belongs to the scope of the present invention.

Generally speaking, for design of the power amplifying module the better anti-distortion effect is required for the amplifier closer to the output end. However, if the power amplifier having a smaller number of HBTs, which has smaller input 1 dB compression point IP_{1dB} and output 1 dB compression point OP_{1dB}, is set closer to the output end, this leads to worse distortion and bad output effect. Consequently, the present power amplifying module is best suited for use in designing high power microwave integrated circuits. This is because that the power amplifier having a higher number of HBTs, which has a lower power gain, larger input 1 dB compression point IP_{1dB} and output 1 dB compression point OP_{1dB},is set closer to the output end, thereby preserving the power gain of the complete power amplifying module and also reducing the distortion risk.

Those skilled in the art will readily observe that numerous modifications and alterations of the device may be made while retaining the teachings of the invention. Accordingly, the above disclosure should be construed as limited only by the metes and bounds of the appended claims.

1. A power amplifying module comprising:
an input end for inputting power;
an output end for outputting amplified power; and
two cascaded power amplifiers, each comprising at least a heterojunction bipolar transistor (HBT) coupled in parallel, wherein the number of HBTs of the amplifier closer to the input end is less than that of the amplifier closer to the output end.

2. The power amplifying module of claim 1 wherein the value of input power of each power amplifier is smaller than that of the input 1 dB compression point of each corresponding amplifier.

3. The power amplifying module of claim 1 wherein the value of output power of each power amplifier is smaller than that of the output 1 dB compression point of each corresponding amplifier.

4. The power amplifying module of claim 1 wherein the output power of the power amplifying module is substantially larger than 10.6 dBm.

5. A method of forming a power amplifying module comprising:
cascading two power amplifiers of which the power amplifier closer to the input end has a smaller number of heterojunction bipolar transistors (HBTs) coupled in parallel than the power amplifier closer to the output end does.

6. The method of claim 5 further comprising adjusting input power of each power amplifier to be smaller than the input 1 dB compression point of each corresponding amplifier.

7. The method of claim 5 further comprising adjusting output power of each power amplifier to be smaller than the output 1 dB compression point of each corresponding amplifier.

8. The method of claim 5 wherein the output power of the power amplifying module is substantially larger than 10.6 dBm.
